(19) United States
(12) Patent Application Publication
(10) Pub. No.: US 2008/0102223 A1
(43) Pub. Date: May 1, 2008

(54) Hybrid layers for use in coatings on electronic devices or other articles

(76) Inventors: Sigurd Wagner, Princeton, NJ (US); Prashant Mandlik, Princeton, NJ (US)

Correspondence Address: KENYON & KENYON LLP, 1500 K STREET N.W., SUITE 700, WASHINGTON, DC, 20005, US

(21) Appl. No.: 11/783,361

(22) Filed: Apr. 9, 2007

Related U.S. Application Data
(60) Provisional application No. 60/856,047, filed on Nov. 1, 2006.

(51) Int. Cl. C23C 16/00

(52) U.S. Cl. 427/585

(57) ABSTRACT

A method for forming a coating over a surface is disclosed. The method comprises depositing over a surface, a hybrid layer comprising a mixture of a polymeric material and a non-polymeric material. The hybrid layer may have a single phase or comprise multiple phases. The hybrid layer is formed by chemical vapor deposition using a single source of precursor material. The chemical vapor deposition process may be plasma-enhanced and may be performed using a reactant gas. The precursor material may be an organo-silicon compound, such as a siloxane. The hybrid layer may comprise various types of polymeric materials, such as silicone polymers, and various types of non-polymeric materials, such as silicon oxides. By varying the reaction conditions, the wt % ratio of polymeric material to non-polymeric material may be adjusted. The hybrid layer may have various characteristics suitable for use with organic light-emitting devices, such as optical transparency, impermeability, and/or flexibility.

This application incorporates by reference in its entirety, U.S. patent application Ser. No. ______, entitled “Multilayered Coatings for Use on Electronic Devices or Other Articles,” by Sigurd Wagner, identified with Attorney Docket No. 10020/35101, and filed on the same date as this application.

The claimed invention was made with support from the United States Government, under Contract No. W911QX-06-C-0017, awarded by the Army Research Office. The U.S. Government may have certain rights in this invention.

### TECHNICAL FIELD

The present invention relates to barrier coatings for electronic devices.

### BACKGROUND

Organic electronic devices, such as organic light-emitting devices (OLEDs), are vulnerable to degradation when exposed to water vapor or oxygen. A protective barrier coating over the OLED to reduce its exposure to water vapor or oxygen could help to improve the lifetime and performance of the device. Films of silicon oxide, silicon nitride, or aluminum oxide, which have been successfully used in food packaging, have been considered for use as barrier coatings for OLEDs. However, these inorganic films tend to contain microscopic defects which allow some diffusion of water vapor and oxygen through the film. In some cases, the defects open as cracks in the brittle film. While this level of water and oxygen diffusion may be acceptable for food products, it is not acceptable for OLEDs. To address these problems, multilayer barrier coatings that use alternating inorganic and polymer layers have been tested on OLEDs and found to have improved resistance to water vapor and oxygen penetration. But these multilayer coatings have the disadvantages of complexity and cost. Thus, there is a need for other methods of forming barrier coatings suitable for use in protecting OLEDs.

### SUMMARY

In one aspect, the present invention provides a method for forming a coating over a surface, comprising: (a) providing a single source of precursor material; (b) transporting the precursor material to a reaction location adjacent a surface to be coated; and (c) depositing a hybrid layer over the surface by chemical vapor deposition using the single source of precursor material, wherein the hybrid layer comprises a mixture of a polymeric material and a non-polymeric material.

The chemical vapor deposition process may be plasma-enhanced and may be performed using an added reactant gas. The precursor material may be an organo-silicon compound, such as a siloxane. The hybrid layer may comprise various types of polymeric materials, such as silicone polymers, and various types of non-polymeric materials, such as silicon oxides. The hybrid layers may have a single phase or multiple phases. By varying the reaction conditions, the weight ratio of polymeric material to non-polymeric material may be adjusted. The hybrid layer may have various characteristics suitable for use with organic light-emitting devices, such as optical transparency, impermeability, and/or flexibility.

### BRIEF DESCRIPTION OF THE DRAWINGS

FIG. 1 shows a schematic diagram of a PE-CVD apparatus that can be used for implementing certain embodiments of the present invention.

FIG. 2 shows a cross-sectional view of a portion of an OLED having a hybrid layer barrier coating.

FIG. 3 shows the results of an accelerated environmental test of bottom-emitting and of transparent OLEDs, each having a hybrid layer barrier coating.

### DETAILED DESCRIPTION

In one aspect, the present invention provides a method for forming a coating over a surface. The method comprises depositing over the surface, a hybrid layer comprising a mixture of a polymeric material and a non-polymeric material. The hybrid layer may have a single phase or multiple phases.

As used herein, the term “non-polymeric” refers to a material made of molecules having a well-defined chemical formula with a single, well-defined molecular weight. A “non-polymeric” molecule can have a significantly large molecular weight. In some circumstances, a non-polymeric molecule may include repeat units. As used herein, the term “polymeric” refers to a material made of molecules that have repeating subunits that are covalently linked, and that has a molecular weight that may vary from molecule to molecule because the polymerizing reaction may result in different numbers of repeat units for each molecule. Polymers include, but are not limited to homopolymers and copolymers such as block, graft, random, or alternating copolymers, as well as blends and modifications thereof. Polymers include, but are not limited to, polymers of carbon or silicon.

As used herein, a “mixture of a polymeric material and a non-polymeric material” refers to a composition that one of ordinary skill in the art would understand to be neither purely polymeric nor purely non-polymeric. The term “mixture” is intended to exclude any polymeric materials that contain incidental amounts of non-polymeric material (that may, for example, be present in the interstices of polymeric materials as a matter of course), but one of ordinary skill in the art would nevertheless consider to be purely polymeric. Likewise, this is intended to exclude any non-polymeric materials that contain incidental amounts of polymeric material, but one of ordinary skill in the art would nevertheless consider to be purely non-polymeric. In some cases, the weight ratio of polymeric to non-polymeric material in the hybrid layer is in the range of 95:5 to 5:95, and preferably in the range of 90:10 to 10:90, and more preferably, in the range of 25:75 to 10:90.

The polymeric/non-polymeric composition of a layer may be determined using various techniques, including wetting contact angles of water droplets, IR absorption, hardness, and flexibility. In certain instances, the hybrid layer has a wetting contact angle in the range of 30° to 85°, and preferably, in the range of 30° to 60°, and more preferably, in the range of 36° to 60°. Note that the wetting contact angle is a measure of composition if determined on the surface of an as-deposited film. Because the wetting contact angle can vary greatly by post-deposition treatments, measurements taken after such treatments may not accurately reflect the layer's composition. It is believed that these wetting contact angles are applicable to a wide range of layers formed from organo-silicon precursors. In certain instances, the hybrid layer has a nano-indentation hardness in the range of 3 to 20 GPa, and preferably, in the range of 10 to 18 GPa. In certain instances, the hybrid layer has a surface roughness (root-mean-square) in the range of 0.1 nm to 10 nm, and preferably, in the range of 0.2 nm to 0.35 nm. In certain instances, the hybrid layer, when deposited as a 4 μm thick layer on a 50 μm thick polyimide foil substrate, is sufficiently flexible that no microstructural changes are observed after at least 55,000 rolling cycles on a 1 inch diameter roll at a tensile strain (ε) of 0.2%. In certain instances, the hybrid layer is sufficiently flexible that no cracks appear under a tensile strain (ε) of at least 0.35% (a tensile strain level which would normally crack a 4μm pure silicon oxide layer, as considered by a person of ordinary skill in the art).

The term “mixture” is intended to include compositions having a single phase as well as compositions having multiple phases. Therefore, a “mixture” excludes subsequently deposited alternating polymeric and non-polymeric layers. Put another way, to be considered a “mixture,” a layer should be deposited under the same reaction conditions and/or at the same time.

The hybrid layer is formed by chemical vapor deposition using a single source of precursor material. As used herein, “single source of precursor material” refers to a source that provides all the precursor materials that are necessary to form both the polymeric and non-polymeric materials when the precursor material is deposited by CVD, with or without a reactant gas. This is intended to exclude methods where the polymeric material is formed using one precursor material, and the non-polymeric material is formed using a different precursor material. By using a single source of precursor material, the deposition process is simplified. For example, a single source of precursor material will obviate the need for separate streams of precursor materials and the attendant need to supply and control the separate streams.

The precursor material may be a single compound or a mixture of compounds. Where the precursor material is a mixture of compounds, in some cases, each of the different compounds in the mixture is, by itself, able to independently serve as a precursor material. For example, the precursor material may be a mixture of hexamethyl disiloxane (HMDSO) and dimethyl siloxane (DMSO).

In some cases, plasma-enhanced CVD (PE-CVD) may be used for deposition of the hybrid layer. PE-CVD may be desirable for various reasons, including low temperature deposition, uniform coating formation, and controllable process parameters. Various PE-CVD processes which are suitable for use in the present invention are known in the art, including those that use RF energy to generate the plasma.

The precursor material is a material that is capable of forming both a polymeric material and a non-polymeric material when deposited by chemical vapor deposition. Various such precursor materials are suitable for use in the present invention and are chosen for their various characteristics. For example, a precursor material may be chosen for its content of chemical elements, its stoichiometric ratios of the chemical elements, and/or the polymeric and non-polymeric materials that are formed under CVD. For instance, organo-silicon compounds, such as siloxanes, are a class of compounds suitable for use as the precursor material. Representative examples of siloxane compounds include hexamethyl disiloxane (HMDSO) and dimethyl siloxane (DMSO). When deposited by CVD, these siloxane compounds are able to form polymeric materials, such as silicone polymers, and non-polymeric materials, such as silicon oxide. The precursor material may also be chosen for various other characteristics such as cost, non-toxicity, handling characteristics, ability to maintain liquid phase at room temperature, volatility, molecular weight, etc.

Other organo-silicon compounds suitable for use as a precursor material include methylsilane; dimethylsilane; vinyl trimethylsilane; trimethylsilane; tetramethylsilane; ethylsilane; disilanomethane; bis(methylsilano)methane; 1,2-disilanoethane; 1,2-bis (methylsilano)ethane; 2,2-disilanopropane; 1,3,5-trisilano-2,4,6-trimethylene, and fluorinated derivatives of these compounds. Phenyl-containing organo-silicon compounds suitable for use as a precursor material include: dimethylphenylsilane and diphenylmethylsilane. oxygen-containing organo-silicon compounds suitable for use as a precursor material include: dimethyldimethoxysilane; 1,3,5,7-tetramethylcyclotetrasiloxane; 1,3-dimethyldisiloxane; 1,1,3,3-tetramethyldisiloxane; 1,3-bis(silanomethylene)disiloxane; bis(1-methyldisiloxanyl)methane; 2,2-bis(1-methyldisiloxanyl)propane; 2,4,6,8-tetramethylcyclotetrasiloxane; octamethylcyclotetrasiloxane; 2,4,6,8,10-pentamethylcyclopentasiloxane; 1,3,5,7-tetrasilano-2,6-dioxy-4,8-dimethylene; hexamethylcyclotrisiloxane; 1,3,5,7,9-pentamethylcyclopentasiloxane; hexamethoxydisiloxane, and fluorinated derivatives of these compounds. Nitrogen-containing organo-silicon compounds suitable for use as a precursor material include: hexamethyldisilazane; divinyltetramethyldisilizane; hexamethylcyclotrisilazane; dimethylbis(N-methylacetamido)silane; dimethylbis-(N-ethylacetamido)silane; methylvinylbis(N-methylacetamido)silane; methylvinylbis(N-butylacetamido)silane; methyltris(N-phenylacetamido)silane; vinyltris(N-ethylacetamido)silane; tetrakis(N-methylacetamido)silane; diphenylbis(diethylaminoxy)silane; methyltris(diethylaminoxy)silane; and bis(trimethylsilyl)carbodiimide.

When deposited by CVD, the precursor material may form various types of polymeric materials in various amounts, depending upon the type of precursor material, the presence of any reactant gases, and other reaction conditions. The polymeric material may be inorganic or organic. For example, where organo-silicon compounds are used as the precursor material, the deposited hybrid layer may include polymer chains of Si—O bonds, Si—C bonds, or Si—O—C bonds to form polysiloxanes, polycarbosilanes, and polysilanes, as well as organic polymers.

When deposited by CVD, the precursor material may form various types of non-polymeric materials in various amounts, depending upon the type of precursor material, the presence of any reactant gases, and other reaction conditions. The non-polymeric material may be inorganic or organic. For example, where organo-silicon compounds are used as the precursor material in combination with an oxygen-containing reactant gas, the non-polymeric material may include silicon oxides, such as SiO, SiO₂, and mixed-valence oxides SiOₓ. When deposited with a nitrogen-containing reactant gas, the non-polymeric material may include silicon nitrides (SiNₓ). Other non-polymeric materials that may be formed include silicon oxycarbide and silicon oxynitrides.

When using PE-CVD, the precursor material may be used in conjunction with a reactant gas that reacts with the precursor material in the PE-CVD process. The use of reactant gases in PE-CVD is known in the art and various reactant gases are suitable for use in the present invention, including oxygen-containing gases (e.g., O₂, ozone, water) and nitrogen-containing gases (e.g., ammonia). The reactant gas may be used to vary the stoichiometric ratios of the chemical elements present in the reaction mixture. For example, when a siloxane precursor material is used with an oxygen or nitrogen-containing reactant gas, the reactant gas will change the stoichiometric ratios of oxygen or nitrogen in relation to silicon and carbon in the reaction mixture. This stoichiometric relation between the various chemical elements (e.g., silicon, carbon, oxygen, nitrogen) in the reaction mixture may be varied in several ways. One way is to vary the concentration of the precursor material or the reactant gas in the reaction. Another way is to vary the flow rates of the precursor material or the reactant gas into the reaction. Another way is to vary the type of precursor material or reactant gas used in the reaction.

Changing the stoichiometric ratios of the elements in the reaction mixture can affect the properties and relative amounts of the polymeric and non-polymeric materials in the deposited hybrid layer. For example, a siloxane gas may be combined with varying amounts of oxygen to adjust the amount of non-polymeric material relative to the polymeric material in the hybrid layer. By increasing the stoichiometric ratio of oxygen in relation to the silicon or carbon, the amount of non-polymeric material, such as silicon oxides, may be increased. Similarly, by reducing the stoichiometric ratio of oxygen, the amount of silicon and carbon-containing polymeric material may be increased. The composition of the hybrid layer may also be varied by adjusting other reaction conditions. For example, in the case of PE-CVD, process parameters such as RF power and frequency, deposition pressure, deposition time, and gas flow rates can be varied.

Thus, by using the methods of the present invention, it is possible to form a hybrid layer of hybrid polymeric/non-polymeric character and having characteristics suitable for use in various applications. Such characteristics include optical transparency, impermeability, flexibility, thickness, adhesion, and other mechanical properties. For example, one or more of these characteristics may be adjusted by varying the weight % of polymeric material in the hybrid layer, with the remainder being non-polymeric material. For instance, to achieve a desired level of flexibility and impermeability, the wt % polymeric material may preferably be in the range of 5 to 95%, and more preferably in the range of 10 to 25%. However, other ranges are also possible depending upon the application.

Barrier layers made of purely non-polymeric materials, such as silicon oxide, can have various advantages relating to optical transparency, good adhesion, and good film stress. However, these non-polymeric layers tend to contain microscopic defects which allow the diffusion of water vapor and oxygen through the layer. Providing some polymeric character to the non-polymeric layer can reduce the permeability of the layer without significantly altering the advantageous properties of a purely non-polymeric layer. Without intending to be bound by theory, the inventors believe that a layer having hybrid polymeric/non-polymeric character reduces the permeability of the layer by reducing the size and/or number of defects, in particular microcracks.

In some cases, the coating of the present invention may have a plurality of hybrid layers, wherein the composition of each hybrid layer can vary independently. In some cases, the weight % ratio of one hybrid layer differs by at least 10 weight % from another hybrid layer in the coating. The thickness of each hybrid layer can also vary independently. The different hybrid layers can be created by sequentially adjusting the reaction conditions used in depositing the hybrid layer. For example, in a PE-CVD process, the amount of reactant gas provided to the reaction mixture may be adjusted sequentially to produce multiple hybrid layers, with each hybrid layer being discrete and having a different composition.

Where the coating has a zone where its composition changes substantially continuously from one elevation to another, a hybrid layer within that zone may be very thin, even as thin as the smallest molecular unit within the coating. For example, the coating may have a zone where the wt % ratio of polymeric material to non-polymeric material varies continuously. The continuous variation may be linear (e.g., the wt % ratio of polymeric to non-polymeric material may steadily increase with higher elevation) or non-linear (e.g., cyclically increasing and decreasing).

The hybrid layer may be deposited over various types of articles. In some cases, the article may be an organic electronic device, such as an OLED. For an OLED, the hybrid layer may serve as a barrier coating that resists permeation of water vapor and oxygen. For example, a hybrid layer having a water vapor transmission rate of less than 10⁻⁶ g/m²/day and/or an oxygen transmission rate of less than 10⁻³ g/m²/day may be suitable for protecting OLEDs. In some cases, the thickness of the hybrid layer can range from 0.1 to 10 μm, but other thicknesses can also be used depending upon the application. Also, hybrid layers having a thickness and material composition that confers optical transparency may be suitable for use with OLEDs. For use with flexible OLEDs, the hybrid layer may be designed to have the desired amount of flexibility. In some cases, the hybrid layer may be used on other articles that are sensitive to degradation upon exposure to the environment, such as pharmaceuticals, medical devices, biologic agents, biological samples, biosensors, or sensitive measuring equipment.

In some cases, the hybrid layer may be used in combination with an unmixed layer that can also be formed by using the same single source of precursor material, such as an unmixed polymeric layer or an unmixed non-polymeric layer. The unmixed layer may be deposited before or after the hybrid layer is deposited.

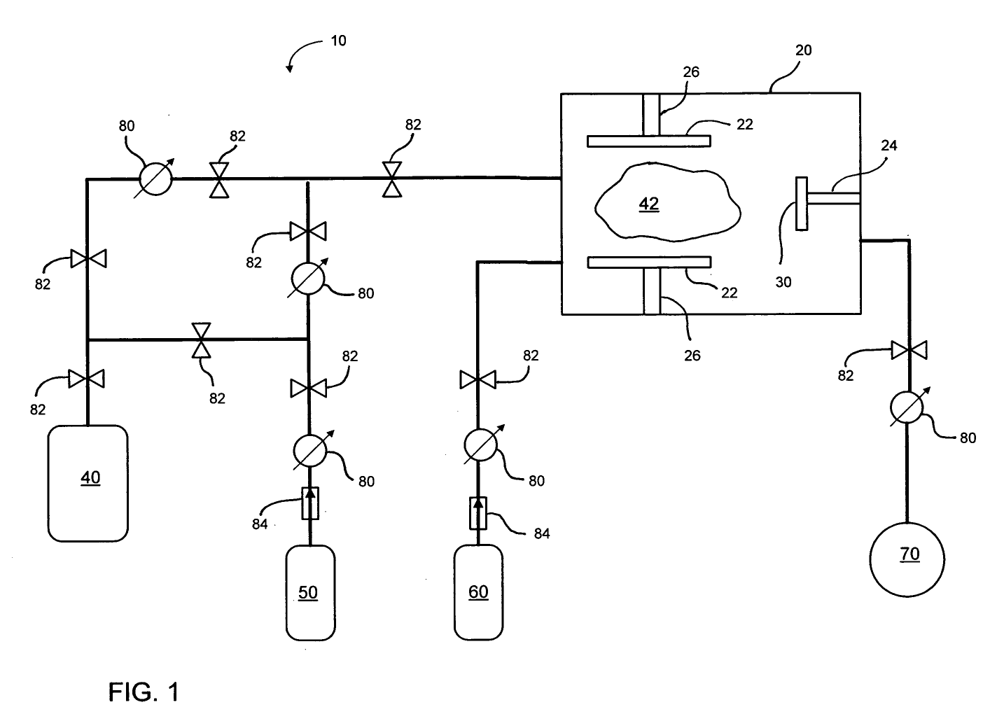

Any of various types of CVD reactors may be used to implement the methods of the present invention. As one example, FIG. 1 shows a PE-CVD apparatus 10 that can be used to implement certain embodiments of the present invention. PE-CVD apparatus 10 comprises a reaction chamber 20 in which an electronic device 30 is loaded onto a holder 24. Reaction chamber 20 is designed to contain a vacuum and a vacuum pump 70 is connected to reaction chamber 20 to create and/or maintain the appropriate pressure. An N₂ gas tank 50 provides N₂ gas for purging apparatus 10. Reaction chamber 20 may further include a cooling system to reduce the heat that is generated by the reaction.

For handling the flow of gases, apparatus 10 also includes various flow control mechanisms (such as mass flow controllers 80, shut-off valves 82, and check valves 84) which may be under manual or automated control. A precursor material source 40 provides a precursor material (e.g., HMDSO in liquid form) which is vaporized and fed into reaction chamber 20. In some cases, the precursor material may be transported to reaction chamber 20 using a carrier gas, such as argon. A reactant gas tank 60 provides the reactant gas (e.g., oxygen), which is also fed into reaction chamber 20. The precursor material and reactant gas flow into reaction chamber 20 to create a reaction mixture 42. The pressure inside reaction chamber 20 may be adjusted further to achieve the deposition pressure. Reaction chamber 20 includes a set of electrodes 22 mounted on electrode standoffs 26, which may be conductors or insulators. A variety of arrangements of device 30 and electrodes 22 are possible. Diode or triode electrodes, or remote electrodes may be used. Device 30 may be positioned remotely as shown in FIG. 1, or may be mounted on one or both electrodes of a diode configuration.

Electrodes 22 are supplied with RF power to create plasma conditions in the reaction mixture 42. Reaction products created by the plasma are deposited onto electronic device 30. The reaction is allowed to proceed for a period of time sufficient to deposit a hybrid layer on electronic device 30. The reaction time will depend upon various factors, such as the position of device 30 with respect to electrodes 22, the type of hybrid layer to be deposited, the reaction conditions, the desired thickness of the hybrid layer, the precursor material, and the reactant gas. The reaction time may be a duration between 5 seconds to 5 hours, but longer or shorter times may also be used depending upon the application.

Table 1 below shows the reaction conditions that were used to make three example hybrid layers. The hybrid layer of Example 1 contained approximately 7% polymeric material and 93% non-polymeric material, as determined from the wetting contact angles of water droplets. The hybrid layer of Example 2 contained approximately 94% polymeric material and 6% non-polymeric material, as determined from the wetting contact angles of water droplets. The hybrid layer of Example 3 contained approximately 25% polymeric material and 75% non-polymeric material, as determined from the wetting contact angles of water droplets. .

TABLE 1

| | HMDSO | HMDSO | | | RF | | Film |
|---|---|---|---|---|---|---|---|
| Hybrid | source | gas flow | O₂ gas flow | Pressure | power | Deposition | thickness |
| Layer | temp (° C.) | rate (sccm) | rate (sccm) | (m torr) | (W) | time (min) | (Å) |
| Example 1 | 33 | 0.4 | 300 | 600 | 5 | 30 | 800 |
| Example 2 | 33 | 10 | 13 | 130 | 18 | 10 | 1,600 |
| Example 3 | 33 | 1.5 | 50 | 150 | 60 | 135 | 60,000 |

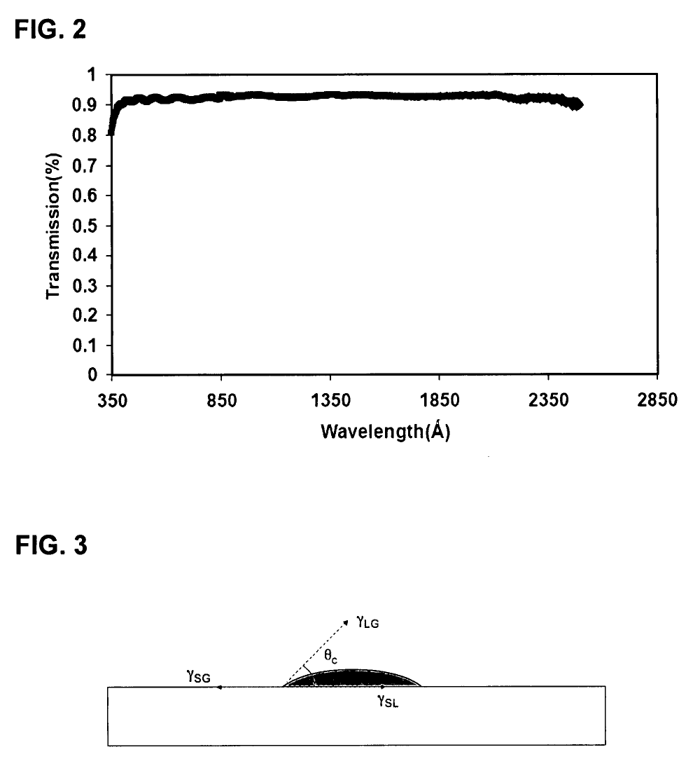

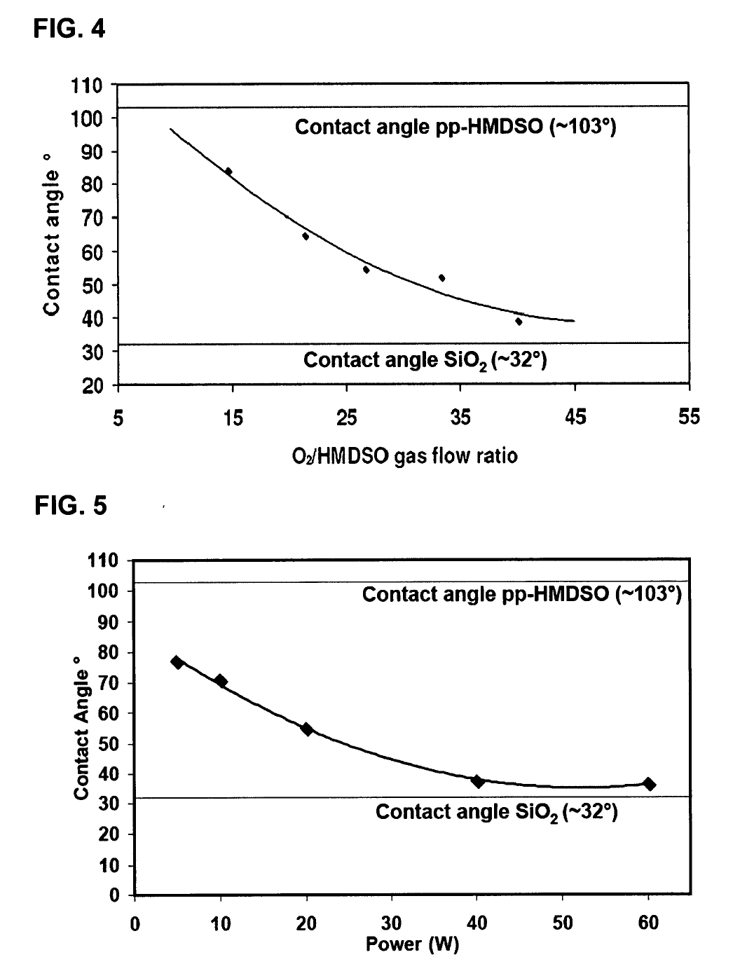

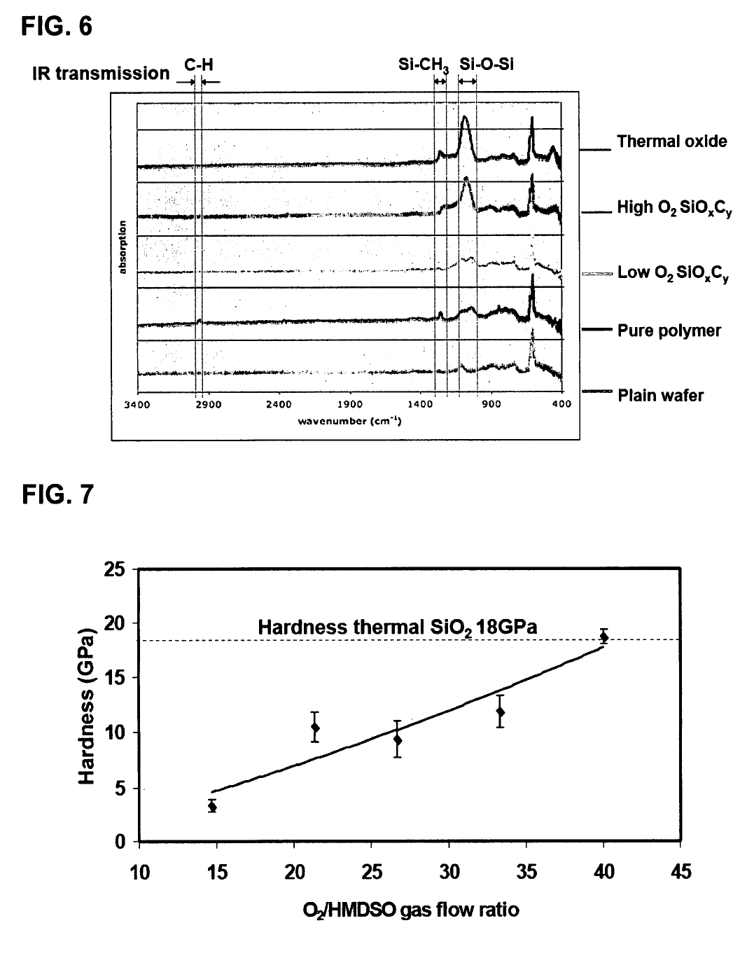

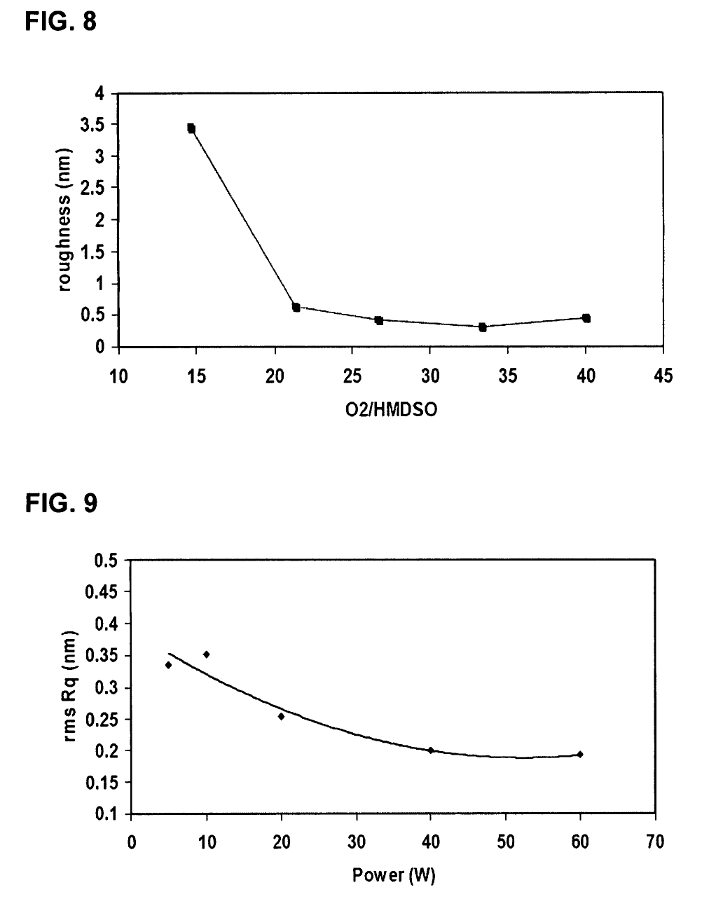

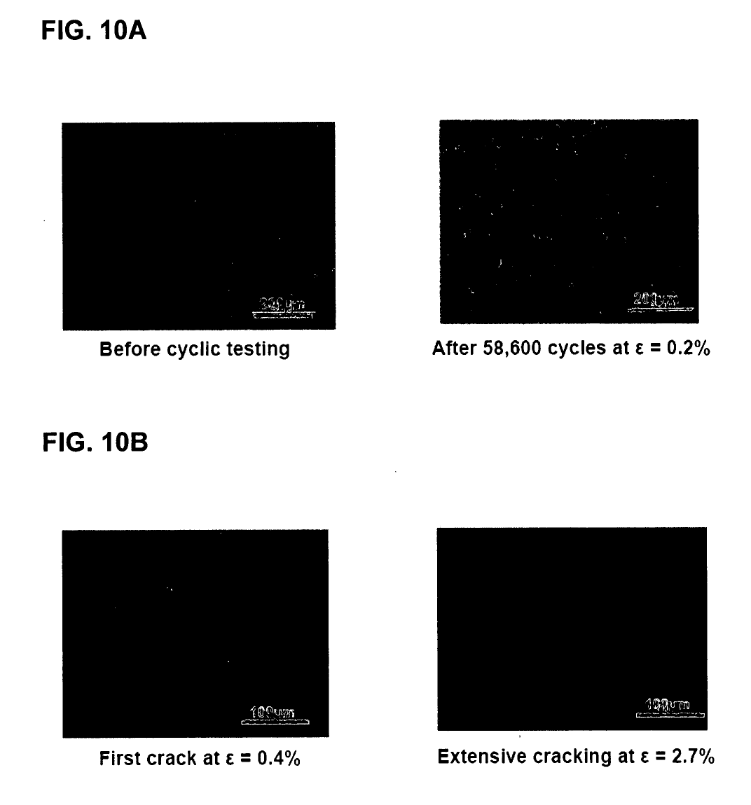

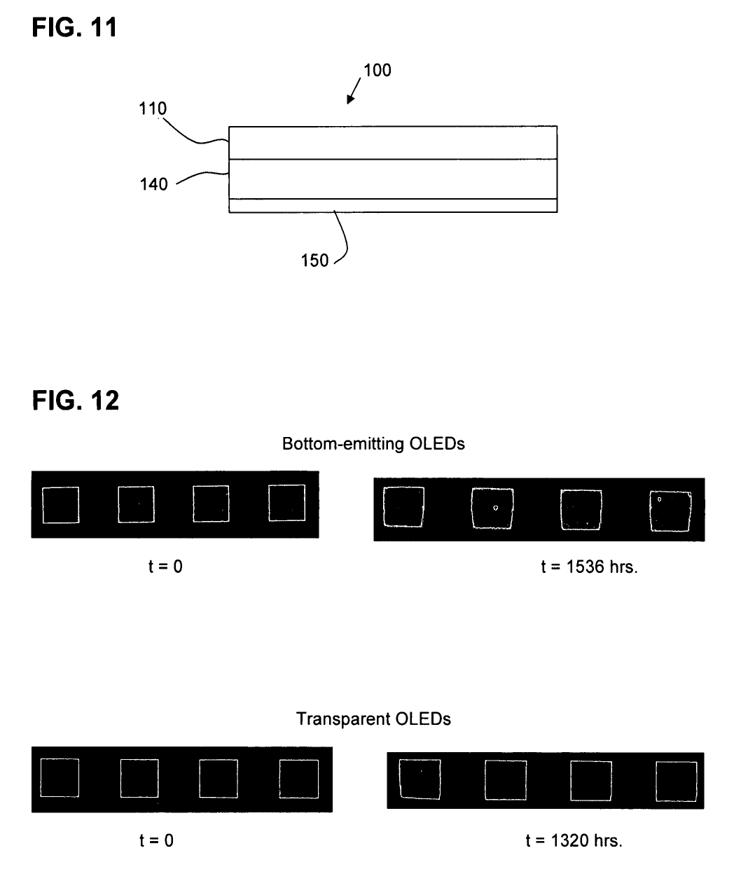

FIG. 2 shows the optical transmission spectrum of the hybrid layer of Example 3. This hybrid layer has greater than 90% transmittance from the near-UV to the near-IR spectrum. FIG. 3 shows how the contact angle of a water droplet on a film is measured. FIG. 4 is a plot of the contact angles of several hybrid layers formed under various O₂/HMDSO gas flow ratios in comparison to the contact angles of a pure SiO₂ film and a pure polymer film. The contact angles of the hybrid layers approach that of a pure SiO₂ film as the oxygen flow rate in the deposition process increases.

FIG. 5 is a plot of the contact angles of several hybrid layers formed under various power levels applied during the PE-CVD process. The contact angles of the hybrid layers approach that of a pure SiO₂ film as the power level increases, which may be due to the fact that higher power levels make O₂ a stronger oxidant. FIG. 6 shows the infrared absorption spectra of hybrid layers formed using a relatively high O₂ flow and a relatively low O₂ flow in comparison to films of pure SiO₂ (thermal oxide) or pure polymer. The high O₂ hybrid layer shows strong peaks in the Si—O—Si band. The nominal peaks in the Si—CH₃ band for the thermal oxide (pure SiO₂ ) film are believed to be related to Si—O vibrations. FIG. 7 is a plot of the nano-indentation hardness of various hybrid layers formed under various O₂/HMDSO gas flow ratios in comparison to the hardness of a pure SiO₂ film. The hardness of the hybrid layers increase as the oxygen flow rate in the deposition process increases, and these hybrid layers can be nearly as hard pure SiO₂ films, and yet be tough and highly flexible.

FIG. 8 is a plot of the surface roughness (root-mean-square), measured by atomic force microscopy, of several hybrid layers formed under various O₂/HMDSO gas flow ratios, and shows that the surface roughness decreases with increasing O₂ flow rates used in the deposition process. FIG. 9 is a plot of the surface roughness (root-mean-square), measured by atomic force microscopy, of several hybrid layers formed under various power levels, and shows that the surface roughness decreases with increasing power levels used in the deposition process.

FIGS. 10A and 10B show optical micrographs of the surface of a 4 μm hybrid layer (deposited under the same source temperature, gas flow rates, pressure, and RF power of Example 3 above) on a 50 μm thick Kapton polyimide foil. In FIG. 10A, the images were obtained before and after the coated foil was subjected to cyclic rolling on a 1 inch diameter roll (tensile strain ε=0.2%). No microstructural changes were observed after 58,600 rolling cycles. In FIG. 10B, the coated foil was subjected to increasing tensile strain, and the images were obtained after the appearance of first cracking (roll diameter of 14 mm) and after extensive cracking (roll diameter of 2 mm). These flexibility results demonstrate that the methods of the present invention can provide a coating that is highly flexible.

FIG. 11 shows a cross-sectional view of a portion of an encapsulated OLED 100, which comprises the OLED proper 140 on a substrate 150, and the hybrid layer of Example 3 above, as a barrier coating 110. FIG. 12 shows the results of accelerated environmental tests of complete OLEDs with barrier coatings. Both bottom-emitting OLEDs and transparent OLEDs were coated with the 6-μm thick hybrid layer of Example 3. The devices were then operated in an environmental chamber at 65° C. and 85% relative humidity. The images show the condition of the OLEDs at the initial time point and after the indicated time intervals. The OLEDs continued to function after well over 1000 hours, demonstrating that the methods of the present invention can provide a coating that effectively protects against the degradative effects of environmental exposure.

What is claimed is:

1. A method for forming a coating over a surface, comprising:
providing a single source of precursor material;
transporting the precursor material to a reaction location adjacent a surface to be coated; and
depositing a hybrid layer over the surface by chemical vapor deposition using the single source of precursor material, wherein the hybrid layer comprises a mixture of a polymeric material and a non-polymeric material, wherein the weight ratio of polymeric to non-polymeric material is in the range of 95:5 to 5:95.

2. The method of claim 1, wherein the precursor material is hexamethyl disiloxane or dimethyl siloxane.

3. The method of claim 1, wherein the precursor material comprises a single organo-silicon compound.

4. The method of claim 1, wherein the precursor material comprises a mixture of organo-silicon compounds.

5. The method of claim 1, wherein the chemical vapor deposition is plasma-enhanced.

6. The method of claim 5, further comprising providing a reactant gas and transporting the reactant gas to the reaction location.

7. The method of claim 6, wherein the reactant gas is oxygen.

8. The method of claim 1, wherein the weight ratio of polymeric to non-polymeric material is in the range of 90:10 to 10:90.

9. The method of claim 1, wherein the weight ratio of polymeric to non-polymeric material is in the range of 25:75 to 10:90.

10. The method of claim 1, wherein the coating comprises a plurality of hybrid layers.

11. The method of claim 10, wherein the plurality of hybrid layers are created by sequentially changing one or more of the reaction conditions in the chemical vapor deposition process.

12. The method of claim 11, further comprising providing a reactant gas and transporting the reactant gas to the reaction location, and wherein the plurality of hybrid layers are created by sequentially changing the amount of reactant gas in the chemical vapor deposition process.

13. The method of claim 12, wherein the plurality of hybrid layers are created by continuously changing one or more of the reaction conditions in the chemical vapor deposition process.

14. The method of claim 13, further comprising providing a reactant gas and transporting the reactant gas to the reaction location, and wherein the plurality of hybrid layers are created by continuously changing the amount of reactant gas in the chemical vapor deposition process.

15. The method of claim 10, wherein the amount of polymeric material in one hybrid layer differs by at least 10 weight % from the amount of polymeric material in another hybrid layer.

16. The method of claim 10, wherein the amount of polymeric material varies continuously from one hybrid layer to another hybrid layer.

17. The method of claim 1, wherein the polymeric material is a silicon-containing polymer.

18. The method of claim 1, wherein the non-polymeric material comprises a silicon-containing compound.

19. The method of claim 18, wherein the silicon-containing compound is inorganic.

20. The method of claim 1, further comprising, before depositing the hybrid layer, depositing an unmixed polymeric layer over the surface using the single source of precursor material.

21. The method of claim 1, further comprising, before depositing the hybrid layer, depositing an unmixed non-polymeric layer over the surface using the single source of precursor material.

22. The method of claim 1, further comprising, after depositing the hybrid layer, depositing an unmixed polymeric layer over the surface using the single source of precursor material.

23. The method of claim 1, further comprising, after depositing the hybrid layer, depositing an unmixed non-polymeric layer over the surface using the single source of precursor material.

24. The method of claim 1, wherein the surface is the surface of a substrate for an electronic device.

25. The method of claim 24, wherein the electronic device is an organic light-emitting device.

26. The method of claim 24, wherein the electronic device is a solar cell.

27. The method of claim 1, wherein the surface is the surface of an electronic device.

28. The method of claim 27, wherein the electronic device is an organic light-emitting device.

29. The method of claim 27, wherein the electronic device is a solar cell.

30. The method of claim 11, wherein the chemical vapor deposition is plasma-enhanced, and wherein the plurality of hybrid layers are created by sequentially changing the plasma power level in the plasma-enhanced chemical vapor deposition process.

31. The method of claim 13, wherein the chemical vapor deposition is plasma-enhanced, and wherein the plurality of hybrid layers are created by continuously changing the plasma power level in the plasma-enhanced chemical vapor deposition process.

32. The method of claim 1, wherein the hybrid layer, as deposited, has a wetting contact angle of a water droplet in the range of 30° to 85°.

33. The method of claim 1, wherein the hybrid layer, as deposited, has a wetting contact angle of a water droplet in the range of 30° to 60°.

34. The method of claim 1, wherein the hybrid layer, as deposited, has a wetting contact angle of a water droplet in the range of 36° to 60°.

35. The method of claim 1, wherein the hybrid layer has a nano-indentation hardness in the range of 3 to 20 GPa.

36. The method of claim 1, wherein the hybrid layer has a nano-indentation hardness in the range of 10 to 18 GPa.

37. The method of claim 1, wherein the hybrid layer has a surface roughness (root-mean-square) in the range of 0.1 to 10 nm.

38. The method of claim 1, wherein the hybrid layer, when deposited as a 4 μm layer on a 50 μm thick polyimide foil substrate, is sufficiently flexible that no microstructural changes are observed after at least 55,000 rolling cycles on a 1 inch diameter roll at a tensile strain (ε) of 0.2%.

39. The method of claim 1, wherein the hybrid layer, when deposited as a 4 μm layer on a 50 μm thick polyimide foil substrate, is sufficiently flexible that no cracks appear under a tensile strain (ε) of at least 0.35%.
